(19) United States
(12) Patent Application Publication
(10) Pub. No.: US 2006/0121194 A1
(43) Pub. Date: Jun. 8, 2006

(54) Method for cleaning a deposition chamber

(75) Inventor: Fumiki Aiso, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 11/295,463

(22) Filed: Dec. 7, 2005

(30) Foreign Application Priority Data
Dec. 8, 2004 (JP) 2004-355473

(51) Int. Cl. B08B 7/00; C23C 16/00

(52) U.S. Cl. 427/248.1; 118/715; 134/19

(57) ABSTRACT

A method for cleaning a deposition chamber of a hot-wall CVD system includes the steps of cleaning the inner s surface of the wall of the deposition chamber and depositing silicon oxide on the inner surface to fill the cracks formed on the inner surface of the wall, which is configured by quartz.

### BACKGROUND OF THE INVENTION

(a) Field of the Invention

The present invention relates to a method for cleaning a deposition chamber in a semiconductor device fabrication system and, more particularly, to a technique suited to cleaning a CVD (Chemical Vapor Deposition) system of a hot-wall type.

(b) Description of the Related Art

Hot-wall CVD systems are generally used for depositing thin films in a semiconductor device. It is known in the hot-wall CVD system that the materials used for deposition or byproducts of the deposition are generally accumulated as deposits on the heated inner surface of a CVD chamber during a normal deposition process in semiconductor wafers The deposits on the inner surface of the wall of the CVD chamber may be peeled off from the inner surface to fall on a wafer and thus cause a malfunction of the product semiconductor device, such as a short-circuit failure. The deposits are generally removed from the inner surface at a specific interval as by a regular wet cleaning process.

The wet cleaning process for the hot-wall CVD system is generally performed after the thickness of the deposits on the inner surface of the CVD chamber reaches a specified thickness. For performing the wet cleaning, the CVD chamber is disassembled, and parts of the CVD chamber subjected to the process gas during the deposition are immersed in a corrosive chemical liquid. However, the wet cleaning process necessitates a longer downtime for the CVD system, thereby reducing the productivity rate of the semiconductor devices. The wet cleaning process may also incur an initial malfunction in the CVD system after the cleaning and assembly thereof.

In view of the malfunction cuased after the assembly, a dry cleaning process, which does not necessitate disassembly, is recently employed for the hot-wall CVD system. FIG. 6 is shows an example of a dry cleaning system used for the hot-wall CVD system.

The hot-wall CVD system 40 exemplified is used for deposition of a silicon nitride film on semiconductor wafers, and includes therein a CVD chamber 11 made of quartz, a chamber container 12 receiving therein the CVD chamber 11, a boat table 13 for mounting thereon a boat 13a which is loaded with a plurality of wafers 19. The boat table 13 is detachably fixed in the chamber 11 and provided with a thermal insulation cylinder 14, which suppresses temperature fluctuation of the wafers 19. The portion of the boat table 13 and thermal insulation cylinder 14 exposed in the chamber 11 is made of quartz.

The chamber 12 is provided with a heater 15 for heating the internal of the chamber 11. The heater 15 is controlled by a temperature controller (not shown) in a feedback control scheme so as to maintain the internal of the chamber 11 at a constant temperature.

The chamber 11 is provided with first and second gas inlet tubes 16, 17 made of quartz on the sides thereof above the boat table 13. The first gas inlet port 16 is coupled to a first gas supply system for supplying a source gas of silicon nitride The first gas supply system includes a gas supply tube 21 coupled to the first gas inlet port 16, and nitrogen (N₂) feeder 23a, ammonium (NH₃) feeder 23b and dichlorosilane (SiH₂Cl₂: DCS) feeder 23c, which are coupled to the upstream end of the gas supply tube 21 via respective mass-flow controllers (MFC) 22a, 22b, 22c.

The second gas inlet port 17 is coupled to a second gas supply system for supplying gas needed for a dry cleaning process. The second gas supply system includes a gas supply tube 24 coupled to the second gas inlet port 17, and fluorine (F₂) feeder 26a and hydrogen fluoride (HF) feeder 26b, which are coupled to the upstream end of the gas supply tube 24 via respective MFCs 25a, 25b. The MFCs 22a, 22b, 2,2c, 26a, 26b control the flow rates of respective gases independently of each other.

The top portion of the chamber 11 is coupled to a gas discharge port 18 for discharging the gas inside the system. The gas discharge port 18 is coupled to a gas exhaust tube 27, which is consecutively coupled to an automatic pressure controller (APC) 28 and a vacuum pump 29. The APC 28 is controlled by a pressure control system (not shown) in a feedback control scheme to maintain the pressure inside the chamber 11 at a specified pressure.

In the deposition process of a silicon nitride film onto wafers 19 by using the CVD system as described above, the DCS and NH₃ gases are used for deposition, with the wafers 19 being received in the boat 13a. After the thickness of the deposits accumulated on the inner surface 11a of the chamber is 11 reaches a specified thickness, a dry cleaning process is conducted with the wafers 19 being removed from the boat 13a, for avoiding contamination of the wafers 19 by particles of the deposits peeled off from the chamber surface 11a. The specified thickness of the deposits is 1 μm, for example, because contamination by the particles of the deposits significantly increases in general after the thickness of the deposits exceeds 1 μm.

FIGS. 7A to 7C are timing charts of a recipe for deposition of silicon nitride, showing the temperature, pressure and gas flow rate profies, respectively, in the chamber 11 during the dry cleaning process. After completion of deposition of a silicon nitride film on the wafers 19, the boat table 13 is detached from the chamber 11, and the wafers 19 are removed from the boat 13. Subsequently, the boat table 13 is again attached onto the chamber 11, which is evacuated to a base pressure to remove the gas from the chamber 11 (t0 to t1).

Thereafter, deposits on the chamber surface 11a are removed by a cleaning step, which includes setting the temperature within the chamber 11 at 300 degrees C. (t2), setting the pressure inside the chamber 11 at about 400 Torr (t3), and supplying F₂ and HF each at a flow rate of 2 slm for about 30 minutes (t4 to t5). The mixing ratio of F₂ to HF should preferably be 1:1, which ratio provides an optimum etch selectivity of silicon nitride from quartz (SiO₂).

The conditions of the cleaning step as described above provide an etching rate of about 700 nm/min. for the silicon nitride film. Thus, the silicon nitride deposits are substantially completely removed from the chamber surface 11a so long as the deposits of accumulated silicon nitride have a thickness of 1 to 1.5 μm.

A cycle purge step is then conducted wherein evacuation to the base pressure and N₂ purge are alternately iterated to remove the F₂ and HF from the chamber 11 (t5 to t6). Subsequently, the temperature inside the chamber 11 is raised up to about 800 degrees C., which is maintained for a specific time interval (not shown), to thereby remove the fluorine-containing reaction products deposited on the chamber surface 11a.

Thereafter, the inner surface 11a of the chamber is pre-coated for suppressing generation of minute particles such as metallic particles from the internal of the chamber wall. The material for the deposition on the wafers 19 is selected as the material for the pre-coat, i.e., silicon nitride in this example. The pre-coat step includes setting the temperature within the chamber 11 at 760 to 780 degrees C. (t7), setting the pressure inside the chamber 11 at about 0.3 Torr (t8), and supplying DCS and NH₃ at flow rates of 0.5 slm and 5 slm, respectively, for about 1.5 to 2.5 hours (t10 to t11, t9 to t12). Those conditions of the pre-coat step provide a deposition rate of about 2 nm/min. for the silicon nitride film, and thus provides silicon nitride film having a thickness of about 0.15 to 0.3 μm.

Thereafter, a cycle purge process is again conducted by alternately iterating evacuation and N₂ purge, thereby removing DCS and NH₃ from the chamber 11 (t13 to t14). Subsequently, inactive gas such as N₂ is supplied to the chamber 11 to resume the atmospheric pressure inside the chamber 11 (t15 to t16). Further, the boat table 13 is detached from the chamber 11, loaded with the boat 13a mounting thereon wafers 19, and then attached onto the chamber 11. A deposition process for the silicon nitride film is then started for manufacturing semiconductor devices.

The dry cleaning process as described above removes the deposits on the inner surface of the chamber without the necessity of disassembling the deposition system, thereby reducing the downtime of the deposition system and improving the productivity rate. The dry cleaning process is described in Patent Publication JP-A-2001-123271, for example.

### DISCLOSURE OF THE INVENTION

(a) Problems to be Solved by the Invention

There is a problem in that the conventional dry cleaning process, after repetition of the dry cleaning process, incurs reduction in the deposition rate of the silicon nitride film immediately after the dry cleaning process is finished. FIG. 8 shows an example of reduction in the deposition rate in the case where the deposition system for the silicon nitride film is regularly cleaned by the dry cleaning system.

The number of deposition steps is plotted on abscissa versus the deposited thickness of the silicon nitride film during the deposition steps, which is plotted on ordinate. In this example, a new deposition chamber is used under the conditions for iteratively depositing a silicon nitride film having a thickness of 0.15 nm, and is cleaned regularly after deposition of an accumulated thickness of 1.2 μm for the silicon nitride film, i.e., after the 8 consecutive depositions of silicon nitride film. In FIG. 8, TOP, BTM and CTR means s the thickness measured for the silicon nitride film on the wafers disposed in the top portion, bottom portion and central portion, respectively, of the chamber.

In FIG. 8, the vertical dotted line corresponds to the dry cleaning stop conducted every eight deposition steps. As lo understood from the same figure, a first deposition step conducted immediately after the dry cleaning step incurs reduction in the deposited thickness after the repetition of the dry cleaning step. It is also understood that the deposition thickness is recovered gradually during the iterated is deposition steps after the first deposition step immediately after the dry cleaning step. The reduction in the deposited thickness is especially noticeable for the wafer disposed in the top portion of the chamber. It should be noted that the reduction in the deposited thickness means the reduction in the deposition rate.

The reduction itself in the deposition rate may be compensated by increasing a deposition time of each deposition step to obtain a desired deposition thickness, However, as shown in FIG. 8, deposition rate differs depending on the location of the wafers in the chamber. In addition, the reduction in the deposition rate fluctuates among the deposition steps iterated. Thus, use of the increased deposition time for the deposition step is difficult to achieve, and does not solve the problem of the reduction in the deposition rate. In view of the above problem in the conventional dry cleaning process, a wet cleaning process is also employed every five consecutive dry cleaning steps, for example, for avoiding the fluctuation and reduction in the deposited thickness.

The wet cleaning step necessitates a longer downtime of the deposition system, and thus it is desired to reduce the number of wet cleaning steps in the fabrication process for semiconductor devices. Especially in the recent technology for fabricating the semiconductor devices, the automation of the fabrication system makes it difficult to accept a downtime for the system, and a larger chamber size employed corresponding to a larger wafer size increases the downtime needed for removing the deposits.

For reducing the number of wet cleaning steps, the quartz configuring the deposition chamber may be etched by employing a smaller etch selectivity between the silicon nitride and the quartz. The etch selectivity may be controlled by adjusting the flow rate ratio between F₂ and HF. The etching of the surface of the quartz may possibly reduce the reduction in the deposition rate of the silicon nitride film. However, the etching of the quartz causes a damage on the deposition chamber itself.

In view of the above problems in the conventional technique, it is an object of the present invention to provide a method for cleaning a deposition chamber in a semiconductor fabrication system, which is capable of suppressing the damages on the chamber and controlling the film deposition rate after performing a dry cleaning process.

(b) Means for Solving the Problems

The present invention provides a method for cleaning a deposition chamber, including the consecutive steps of: removing deposits from an inner surface of a wall of the deposition chamber; and depositing a material on the inner surface using a chemical vapor deposition process, the material being same as the material configuring the wall.

In accordance with the method of the present invention, the cracks formed on the inner surface of the wall of the deposition chamber are filled with the material same as the material configuring the wall. Thus, the damages formed on the deposition chamber during a film deposition process are removed and the increased area of the inner surface can be reduced, thereby suppressing the reduction in the deposition rate of the film on the wafers.

The above and other objects, features and advantages of the present invention will be more apparent from the following description, referring to the accompanying drawings.

### BRIEF DESCRIPTION OF THE DRAWINGS

FIG. 1 is schematic sectional view of a deposition chamber in a semiconductor fabrication system, according to a first embodiment of the present invention.

FIGS. 2A to 2C are timing charts of a cleaning recipe of the deposition chamber for a silicon nitride film, showing the temperature, pressure and gas flow rate profiles, respectively, in the deposition chamber of the first embodiment.

FIG. 3 is a graph showing the relationship between the number of deposition steps and the film thickness for the dry cleaning process.

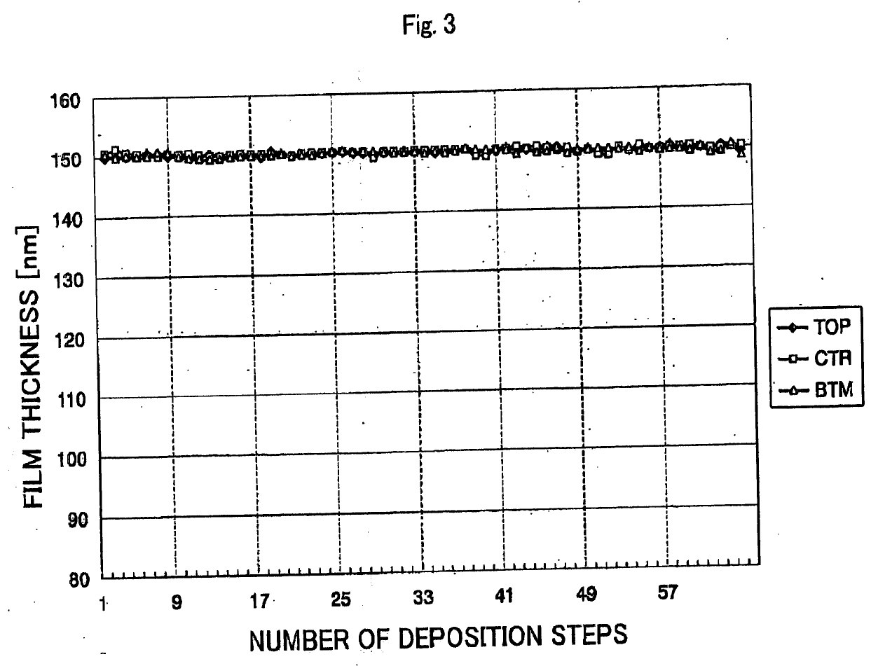

FIG. 4 is a schematic sectional view of a deposition chamber in a semiconductor fabrication system, according to a second embodiment of the present invention.

FIGS. 5A to 5C are timing charts of a cleaning recipe of the deposition chamber for depositing a silicon nitride film, showing the temperature, pressure and gas flow rate profiles, respectively, in the deposition chamber of the second embodiment.

FIG. 6 is schematic sectional view of a conventional semiconductor fabrication system including a dry cleaning system.

FIGS. 7A to 7C are timing charts of a cleaning recipe for depositing a silicon nitride film, showing the temperature, pressure and gas flow rate profiles, respectively, in the conventional deposition chamber.

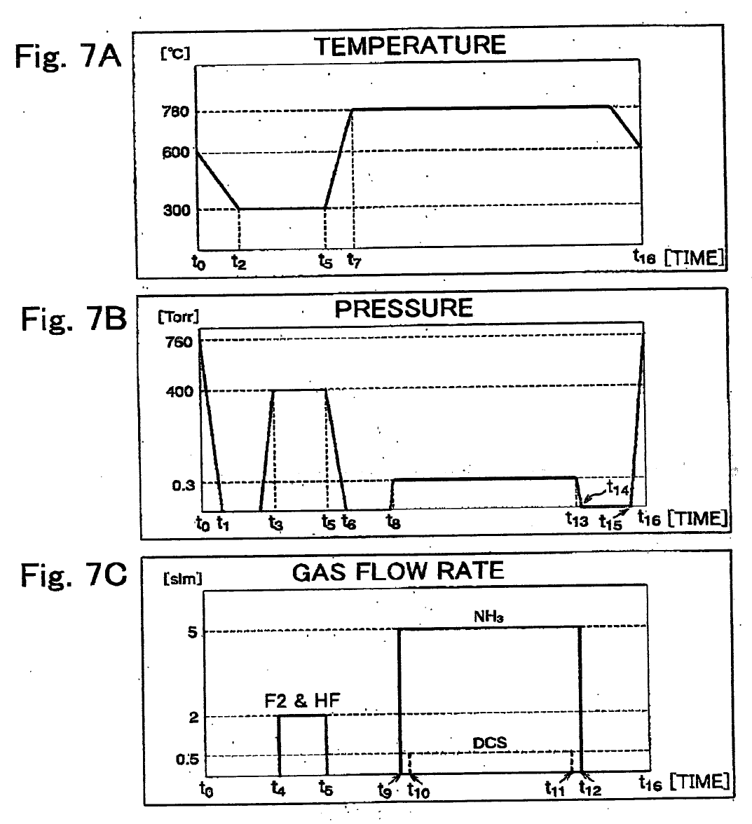

FIG. 8 is a graph showing the relationship between the number of deposition steps and the film thickness for the dry cleaning process.

FIGS. 9A to 9C are sectional views of the wall of the conventional deposition chamber.

### PREFERRED EMBODIMENT OF THE INVENTION

Before describing embodiments of the present invention, the principle of the present invention will be described for a better understanding of the present invention.

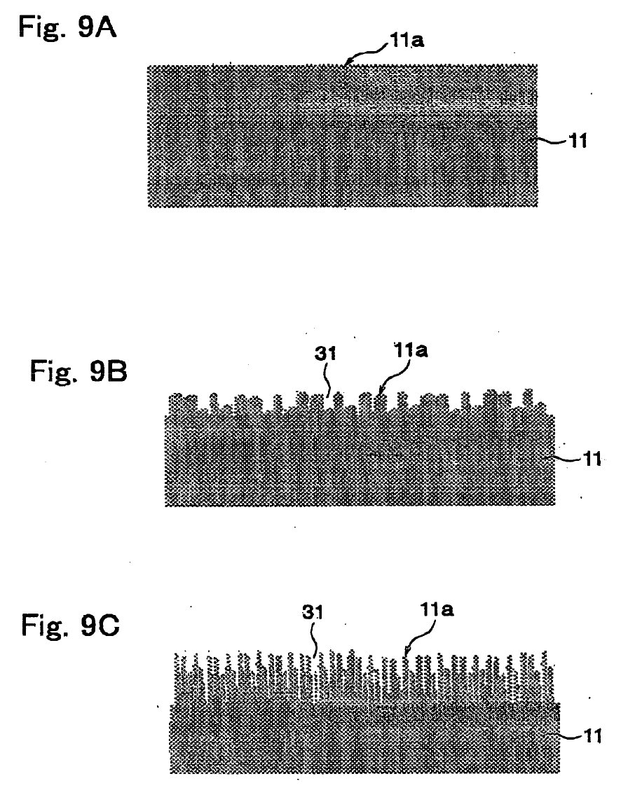

The present inventors investigated the causes of the reduction in the depositing rate of the deposition step conducted immediately after the dry etching step in the conventional technique. FIGS. 9A to 9C show different states of the inner surface of the wall of the deposition chamber. A new deposition chamber has an inner surface such as shown in FIG. 9A, wherein the deposition chamber 11 has a flat inner surface 11a. The deposits of silicon nitride, accumulated on the chamber surface 11a after iterative deposition steps, have a large compressive stress therein. The compressive stress of the deposits may be as high as about 1.0 to 1.5 GPa if the deposits have a thickness of 1 μm or above. The high compressive stress generates minute cracks 31 on the chamber surface 11a, as, shown in FIG. 9B, thereby increasing the area of the chamber surface 11a.

The cracks 31 on the chamber surface 11a may be effectively filled with a pre-coating material, i.e., silicon nitride, if one or two dry cleaning steps are conducted in the deposition chamber before the pre-coat step. If this is the case, the deposits do not have a substantial influence on the fabrication process. However, if the deposition step is iterated for several times before the pre-coat step, the chamber surface 11a has a larger roughness, as shown in FIG. 9C, and may have cracks having a depth of several micrometers, which increases the area of the chamber surface is by hundred times the surface area of the new deposition chamber shown in FIG. 9A.

The large surface area does not allow the pre-coat to effectively fill the cracks 31 so long as the pre-coat step deposits a silicon nitride film having a thickness of around 0.3 μm. The remaining cracks 31 not filled causes the silicon nitride deposition step to deposit a larger amount of silicon nitride film on the chamber surface, resulting in an insufficient amount of source gas for deposition on the wafers. The insufficient amount of source gas reduces the deposition rate of the silicon nitride film, especially in the top portion of the deposition chamber, because the source gas is consumed in the bottom portion or central portion before reaching the top portion of the chamber.

Based on the results of the above investigation, the present invention adopts the step of depositing quartz, i.e., silicon oxide on the inner surface of the wall of the deposition chamber to fill the cracks on the inner surface, the quartz configuring the wall of the deposition chamber. The silicon oxide filling the cracks reduces the increased surface area, to prevent the reduction in the deposition rate, which is incurred immediately after the dry cleaning step. The effectiveness of this technique was assured using a variety of experimental process steps to achieve the present invention.

Now, the present invention is more specifically described with reference to accompanying drawings, wherein similar constituent elements are designated by similar reference numerals throughout the drawings.

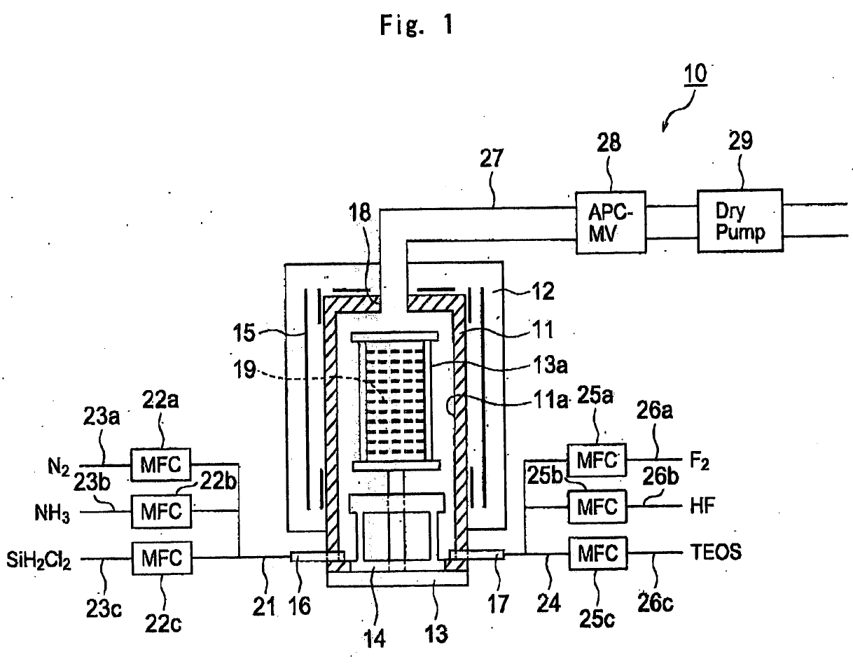

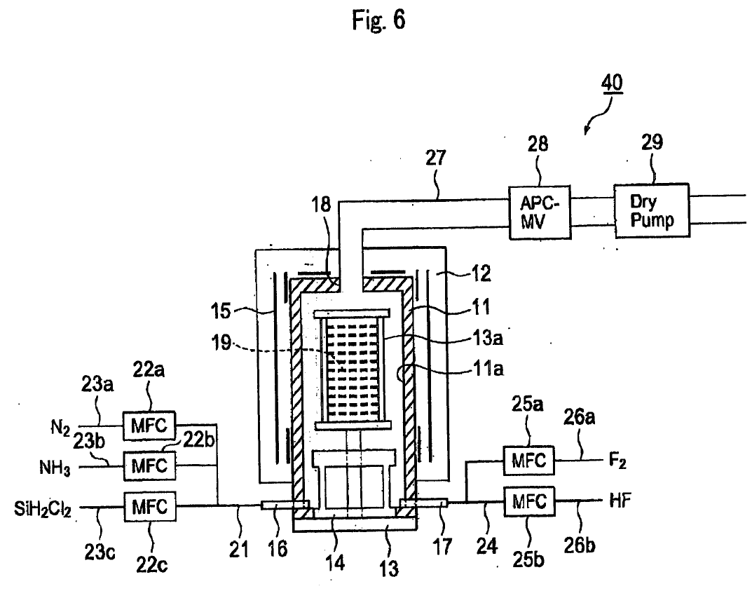

Referring to FIG. 1, a semiconductor device fabrication system according to a first embodiment of the present invention is similar to the fabrication system shown in FIG. 6, except for the configuration of the second gas supply system.

More specifically, the semiconductor fabrication system, generally designated by numeral 10, includes a hot-wall CVD system and a dry cleaning system. The CVD system includes a deposition chamber 11 made of quartz, a chamber container 12 receiving therein the deposition chamber 11, a boat table 13 supporting a boat 13a mounting thereon a plurality of wafers 19, and a thermal insulation cylinder 14 for thermally insulating the boat 13a from the chamber wall 11a. The boat table 13 is detachably fixed on the bottom of the chamber 11. The portion of the boat table 13 and the thermal insulation cylinder exposed in the chamber 11 is made of quartz.

The chamber container 12 is provided with a plurality of heaters for heating the chamber 11. The heaters 15 are controlled by a heater controller in a feedback control so as to maintain the chamber 11 at a specified temperature.

The chamber 11 is provided with first and second gas inlet ports 16, 17 made of quartz above the boat table 13. The first gas inlet port 16 is coupled to a first gas supply system for supplying source gas used for depositing a silicon nitride film. The first gas supply system includes a gas supply tube 21, and N₂ feeder 23a, NH₃ feeder 23b and DCS feeder 23c, which are coupled to the upstream end of the gas supply tube 21 via respective MFCs 22a, 22b, 22c.

The second gas supply port 17 is coupled to a second gas supply system belonging to the dry cleaning system. The second gas supply system includes a gas supply tube 24, and F₂ feeder 26a, HP feeder 26b and tetraethoxysilane (TEOS) feeder 26c, which are coupled to the upstream end of the second gas supply tube 24 via respective MFCs 22a, 22b, 22c. The MFCs 22a, 22b, 22c are capable of controlling respective gases independently of each other.

On top of the chamber 11, there is provided a gas discharge port 18 for discharging the gas inside the chamber 11. The gas discharge port 18 is coupled to a gas exhaust tube 27, which is consecutively coupled with APC 28 and vacuum pump 29. The APC 28 is controlled by a pressure control system (not shown) in a feedback control so as to maintain the internal of the chamber 11 at a specified pressure.

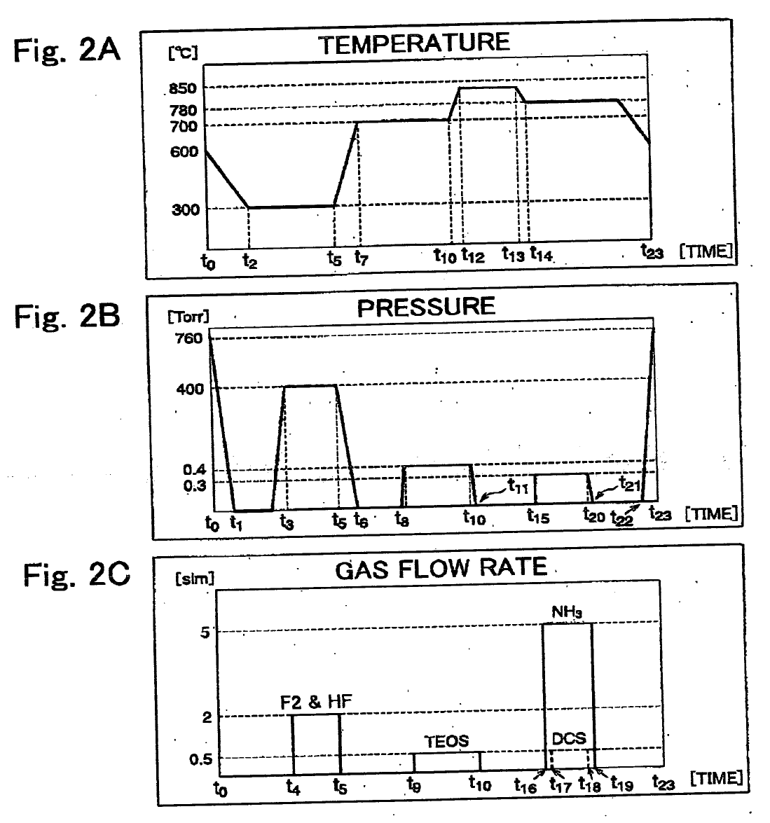

FIGS. 2A to 2C are timing charts of a cleaning recipe showing temperature, pressure and gas flow rate profiles, respectively, in the chamber 11 during a dry cleaning process according to the present embodiment. The dry cleaning process of the present embodiment is similar to the conventional dry cleaning process except for a silicon oxide deposition step in the present embodiment, which is performed prior to the pre-coat step using silicon nitride.

After a silicon nitride film is deposited on the wafers 19 by using the hot-wall deposition system of FIG. 1, the boat table 13 is detached from the chamber 11, and wafers 19 are removed from the boat 13a. Thereafter, the boat table 13 is attached onto the chamber 11, which is evacuated using the vacuum pump 29 to completely remove the gas inside the chamber 11 (t0 to t1). Subsequently, a cleaning step is performed to remove the deposits from the inner surface 11a of the chamber 11. The cleaning step includes setting the temperature of the chamber 11 at 300 degrees C. (t2), setting the internal pressure of the chamber 11 at about 400 Torr (t3), and introducing F₂ and HF each at a flow rate of 1 to 2 slm for about 30 minutes (t4 to t5).0

Under the conditions for the cleaning step, an etch rate of about 700 nm/min. can be obtained for the silicon nitride. Thus, silicon nitride deposits hating a thickness of 1.0 to 1.5 μm can be substantially completely removed from the inner surface 11a of the chamber 11 by the cleaning step. A cycle purge process, wherein evacuation to the base pressure and N₂ purge are alternately iterated, is then performed to completely remove the F₂ and HF from the chamber 11 (t5 to t6).

Thereafter, a silicon oxide film is deposited on the inner surface 11a of the chamber 11 by using a CVD technique. This deposition step includes setting the temperature of the chamber 11 at 700 degrees C. (t7), setting the internal pressure of the chamber 11 at 0.4 Torr (t8), and supplying TEOS at a flow rate of 0.5 slm for 30 minutes (t9 to t10). These conditions provide a deposition rate of 6 to 7 nm/min. for the silicon oxide film, and thus provides a thickness of about 2 μm for the silicon oxide film on the inner surface 11a of the chamber 11.

After stopping the TEOS supply at t10, the chamber 11 is evacuated (t11), and maintained at a temperature of 800 to 850 degrees C. for a specified time length (t12 to t13). This temperature is higher than the deposition temperature for the silicon nitride, thereby modifying the deposited silicon oxide film and desorbing the gas in the deposited silicon oxide film.

Thereafter, a pre-coat step is performed for depositing silicon nitride on the inner surface Ha of the chamber 11. The pre-coat step includes setting the temperature inside the chamber 11 at 760 to 780 degrees C. (t14), setting the internal pressure of the chamber 11 at about 0.3 Torr (t15), and supplying DCS and NH₃ at flow rates of 0.5 slm and 5 slm, respectively, for about 25 minutes (t17 to t18, t16 to t19).

Thereafter, a cycle purge process, wherein evacuation and N₂ purge are alternately iterated, is performed to completely remove DCS and NH₃ from the chamber 11 (t20 to t21). Subsequently, inactive gas such as N₂ is supplied to resume the atmospheric pressure inside the chamber 11 (t22 to t23). Further, the boat table 13 is detached from the chamber 11, loaded with boat 13a mounting thereon wafers 19, and attached onto the bottom of the chamber 11. The fabrication system is then used to deposit a silicon nitride film on the wafers.

According to the present embodiment, the cracks formed on the inner surface 11a of the chamber 11 is filled with the silicon oxide film for reparation of the chamber 11. This reduces the increased surface area of the chamber 11, and restore the deposition rate of the silicon nitride film on the wafers, which is significantly reduced immediately after the dry cleaning step in the conventional technique. The filling of the cracks by using the silicon oxide restores the structure of the chamber. Use of the TEOS for deposition of the silicon oxide film provides a higher deposition rate.

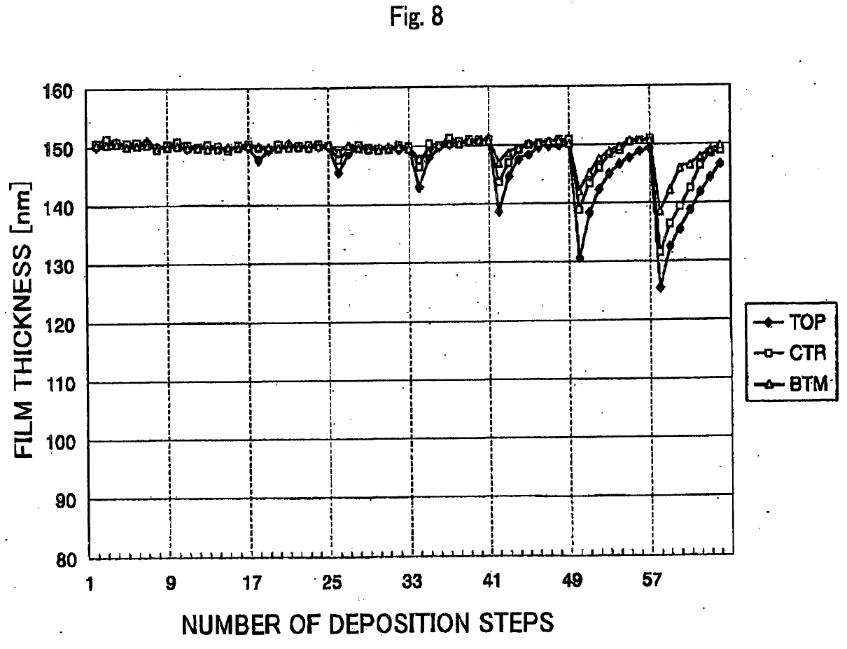

For assuring the advantages of the present invention, the relationship between the number of deposition steps and the deposition rate was investigated by experimental processes. FIG. 2 shows, similarly to FIG. 8, the relationship obtained by the experimental processes. As understood from FIG. 2, the method of the present embodiment is substantially free from the reduction in the deposition rate immediately after the dry cleaning process.

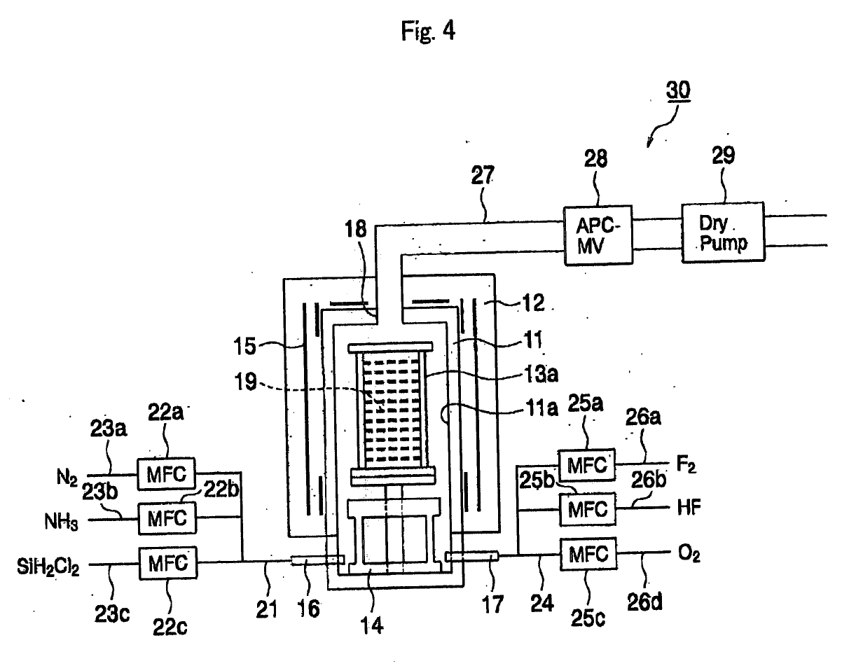

FIG. 4 shows a semiconductor fabrication system including a hot-wall deposition system and a dry cleaning system using a cleaning method according to a second embodiment of the present invention. The fabrication system of the present embodiment is similar to the first embodiment except that the TEOS feeder 26c in the first embodiment is replaced by an oxygen (O₂) feeder 26d.

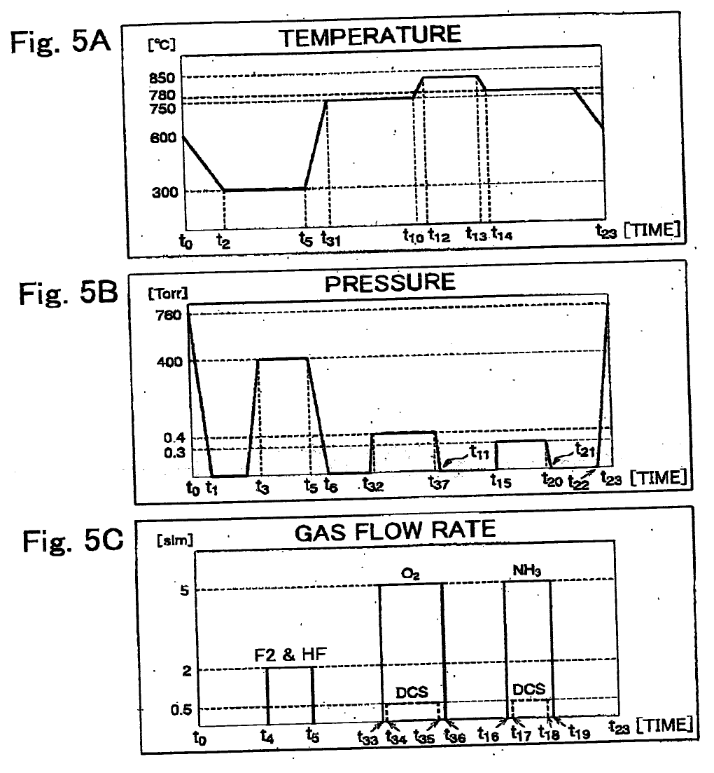

FIGS. 5A to 5C are timing charts of a cleaning recipe showing temperature, pressure and gas flow rate profiles in the chamber 11 during the dry cleaning process of the present embodiment. The dry cleaning process of the present embodiment is similar to the process of the first embodiment described with reference to FIGS. 2A to 2C, except that the silicon oxide deposition step in the present embodiment is different from that in the first embodiment.

More specifically, the silicon oxide deposition step in the present embodiment includes setting the temperature inside the chamber 11 at 750 degrees C. (t31), setting the internal pressure of the chamber 11 at about 0.4 Torr (t32), and supplying DCS and O₂ at flow rates of 0.5 slm and 5 slm, respectively, for about 1.5 hours (t34 to t35, t33 to t36). Those conditions of the deposition process provide a deposition rate of 2 nm/min. for the silicon oxide film., and thus provide a silicon oxide film having a thickness of 2 μm on the chamber surface 11a.

According to the present embodiment, the O₂ feeder 26d provides a lower cost for the silicon oxide depositing step. In the first and second embodiments, the source gas for silicon oxide may include silane, disilane or an organic material, and oxidizing gas may include H₂O, N₂O, O₃ etc.

The deposition system may deposit a polysilicon film on the wafers instead of silicon nitride film. In this cases the cleaning process includes depositing the polysilicon film on the wafers, etching the deposits of polysilicon on the inner surface of the chamber, and depositing polysilicon on the inner surface.

If the deposition chamber is made of aluminum oxide (alumina) instead of quartz, alumina is deposited on the chamber surface 13a instead of quartz. The alumina may be deposited using trimethylaluminum (Al(CH)₃) and oxidizing gas, which are reacted to deposit alumina. The cracks on the chamber surface are filled with alumina for restore the inner surface of the chamber.

In both the first and second embodiments, a thermal cleaning process is used as the step for removing the deposits However, the present invention can be applied to a plasma-enhanced cleaning process instead of the thermal cleaning process.

Since the above embodiments are described only for examples, the present invention is not limited to the above embodiments and various modifications or alterations can be easily made therefrom by those skilled in the art without departing from the scope of the present invention.

What is claimed is:

1. A method for cleaning a deposition chamber, comprising the consecutive steps of:
removing deposits from an inner surface of a wall of the deposition chamber; and
depositing a material on said inner surface using a chemical vapor deposition process, said material being same as the material configuring said wall.

2. The method according to claim 1, wherein said deposition chamber is a hot-wall deposition chamber.

3. The method according to claim 1, wherein said removing step and depositing step are performed in an interval between the steps of depositing a film on a wafer.

4. The method according to claim 3, wherein said film includes one of silicon nitride and silicon oxide.

5. The method according to claim 1, wherein said material is silicon oxide.

6. The method according to claim 1, wherein said material is aluminum oxide.
